(19) United States
(12) Patent Application Publication
(10) Pub. No.: US 2024/0313024 A1
(43) Pub. Date: Sep. 19, 2024

(54) PACKAGE STRUCTURE AND MANUFACTURING METHOD THEREOF

(71) Applicant: Powertech Technology Inc., Hsinchu County (TW)

(72) Inventor: Shang-Yu Chang Chien, Hsinchu County (TW)

(73) Assignee: Powertech Technology Inc., Hsinchu County (TW)

(21) Appl. No.: 18/523,907

(22) Filed: Nov. 30, 2023

(30) Foreign Application Priority Data
Mar. 16, 2023 (TW) 112109855

(51) Int. Cl. H01L 27/146; H01L 23/00; H01L 23/31; H01L 23/498; H01L 23/538; H01L 25/18

(52) U.S. Cl. CPC H01L 27/14634; H01L 23/3128; H01L 23/49811; H01L 23/5383; H01L 23/562; H01L 24/16; H01L 24/32; H01L 24/73; H01L 25/18; H01L 2224/16227; H01L 2224/32225; H01L 2224/73204

(57) ABSTRACT

A package structure including a first redistribution circuit structure, a chip, a second redistribution circuit structure, a plurality of packages, and a plurality of limiting connectors is provided. The chip is disposed on the first redistribution circuit structure. The second redistribution circuit structure is disposed on the chip. The plurality of packages are disposed on the second redistribution circuit structure. Each of the packages includes an encapsulant. The plurality of limiting connectors are disposed between each of the packages and the second redistribution circuit structure.

### CROSS-REFERENCE TO RELATED APPLICATION

This application claims the priority benefit of Taiwan application serial no. 112109855, filed on Mar. 16, 2023. The entirety of the above-mentioned patent application is hereby incorporated by reference herein and made a part of this specification.

### BACKGROUND

### Technical Field

The disclosure relates to a package structure and a manufacturing method thereof, and in particular to a package structure including limiting connectors and a manufacturing method thereof.

### Description of Related Art

In a stacked package structure, it is often necessary to stack chips or packages on top of each other. In the process of stacking, there may be a phenomenon of structural collapse, thus reducing process yield or product quality.

### SUMMARY

The disclosure provides a package structure and a manufacturing method thereof that may have better quality and/or process yield.

A package structure of the disclosure includes a first redistribution circuit structure, at least one third chip, a third encapsulant, a second redistribution circuit structure, a conductive connector, a first package, a second package, and a plurality of limiting connectors. The third chip is disposed on the first redistribution circuit structure. The third encapsulant is disposed on the first redistribution circuit structure and covers the third chip. The second redistribution circuit structure is disposed on the third encapsulant and electrically connected to the third chip. The conductive connector penetrates through the third encapsulant so that the first redistribution circuit structure and the second redistribution circuit structure are electrically connected. The first package is disposed on the second redistribution circuit structure. The first package includes a first chip and a first encapsulant covering the first chip. The second package is disposed on the second redistribution circuit structure. The second package includes a second chip and a second encapsulant covering the second chip. The plurality of limiting connectors are disposed between the first package and the second redistribution circuit structure and between the second package and the second redistribution circuit structure.

A package structure of the disclosure includes a first redistribution circuit structure, a chip, a second redistribution circuit structure, a plurality of packages, and a plurality of limiting connectors. The chip is disposed on the first redistribution circuit structure. The second redistribution circuit structure is disposed on the chip. The plurality of packages are disposed on the second redistribution circuit structure. Each of the packages includes an encapsulant. The plurality of limiting connectors are disposed between each of the packages and the second redistribution circuit structure. The limiting connectors are not structures made entirely of solder.

A manufacturing method of a package structure of the disclosure includes the following steps: disposing at least one third chip on a first redistribution circuit structure; forming a conductive connector on the first redistribution circuit structure; forming a third encapsulant on the first redistribution circuit structure, wherein the third encapsulant covers the third chip; after the conductive connector and the third encapsulant are formed, the conductive connector penetrates through a third encapsulant; forming a second redistribution circuit structure on the third encapsulant, wherein the second redistribution circuit structure is electrically connected to the third chip, and the first redistribution circuit structure and the second redistribution circuit structure are electrically connected by the conductive connector; and disposing a first package and a second package on the second redistribution circuit structure, and there are a plurality of limiting connectors between the first package and the second redistribution circuit structure and between the second package and the second redistribution circuit structure, wherein the first package includes a first chip and a first encapsulant covering the first chip, and the second package includes a second chip and a second encapsulant covering the second chip.

Based on the above, in the manufacturing process of the package structure, the process yield and/or the quality of the package structure may be improved by the limiting connectors used.

### BRIEF DESCRIPTION OF THE DRAWINGS

FIG. 1A to FIG. 1L are partial cross-sectional schematic views of a partial manufacturing method of a package structure according to the first embodiment of the disclosure.

FIG. 1M is a schematic partial cross-sectional view of a package structure according to the first embodiment of the disclosure.

FIG. 1N is a schematic partial top view of a package structure according to the first embodiment of the disclosure.

FIG. 2 is a schematic partial cross-sectional view of a package structure according to the second embodiment of the disclosure.

FIG. 3 is a schematic partial cross-sectional view of a package structure according to the third embodiment of the disclosure.

### DESCRIPTION OF THE EMBODIMENTS

Unless expressly stated otherwise, directional terms (e.g., up, down, left, right, front, back, top, bottom) used herein are used by way of reference only and are not intended to imply absolute orientation.

Any method described herein is in no way intended to be construed as requiring the steps thereof to be performed in a particular order, unless expressly stated otherwise.

The singular forms “a”, “the”, “said”, and similar terms include plural references unless expressly stated otherwise.

Similar terms such as “first”, “second”, and “third” may be used to describe various elements, but these elements should not be limited by these terms. These terms are used only to distinguish one element from another, and do not define an order of execution or a structural orientation relationship.

The disclosure will be described more fully with reference to the drawings of the present embodiments. However, the disclosure may also be embodied in various forms and should not be limited to the embodiments described herein. The thickness, size, or magnitude of layers or regions in the drawings is exaggerated for clarity. The same or similar reference numerals indicate the same or similar elements, which will not be repeated one by one in the following descriptions.

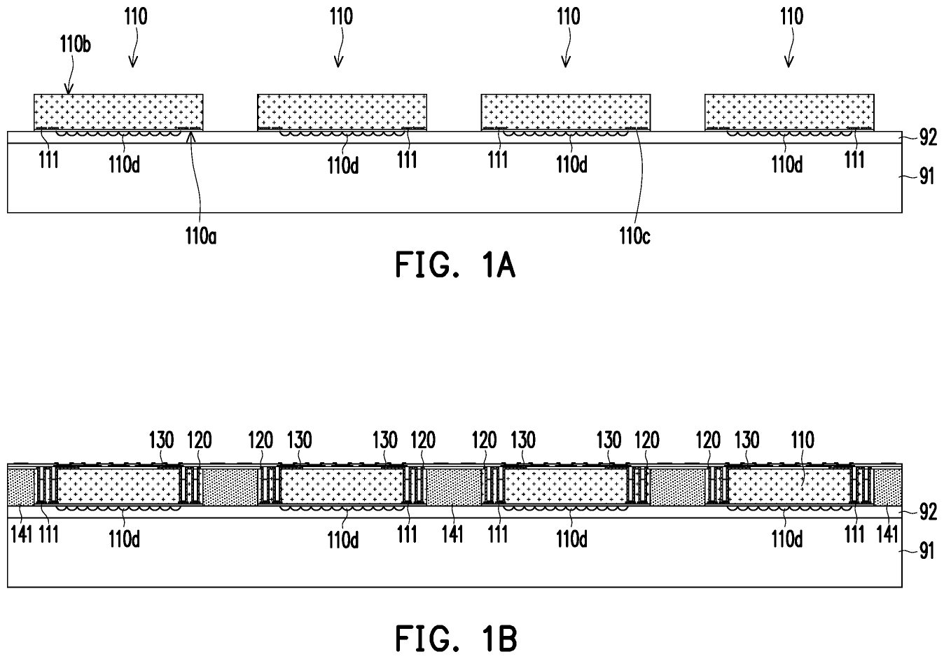

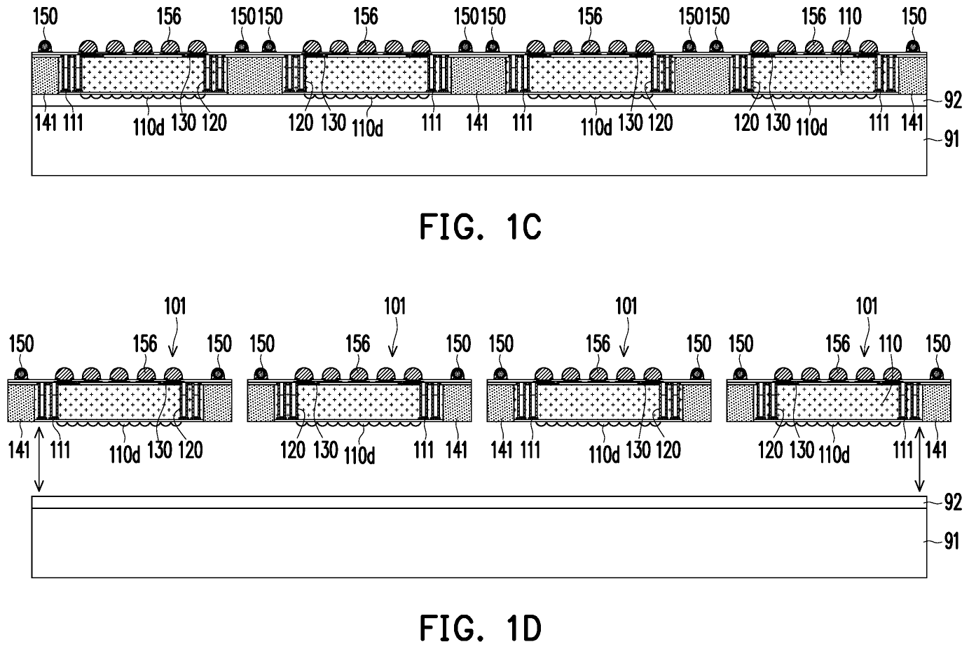

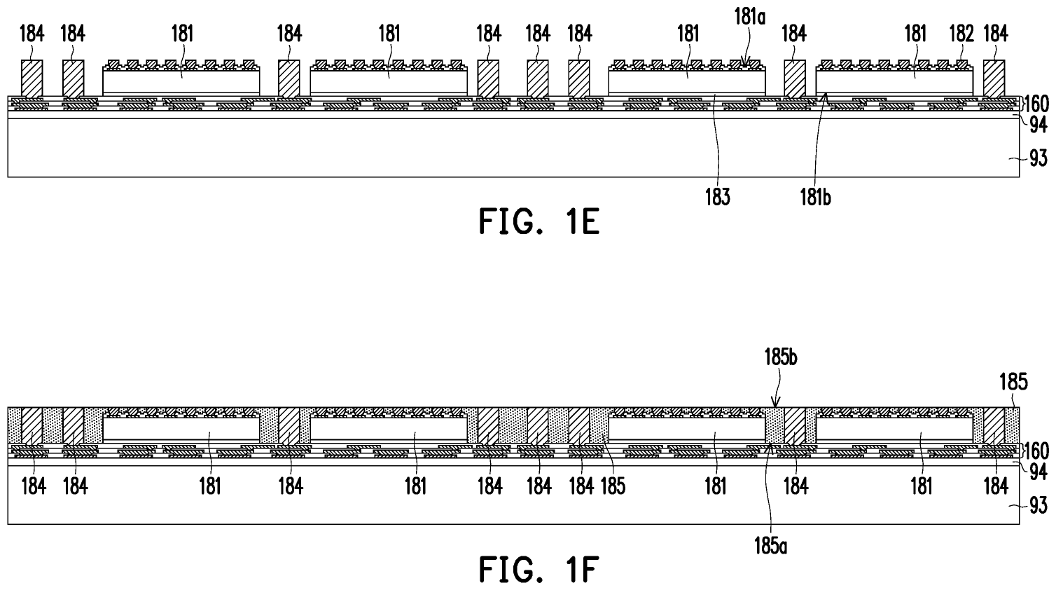

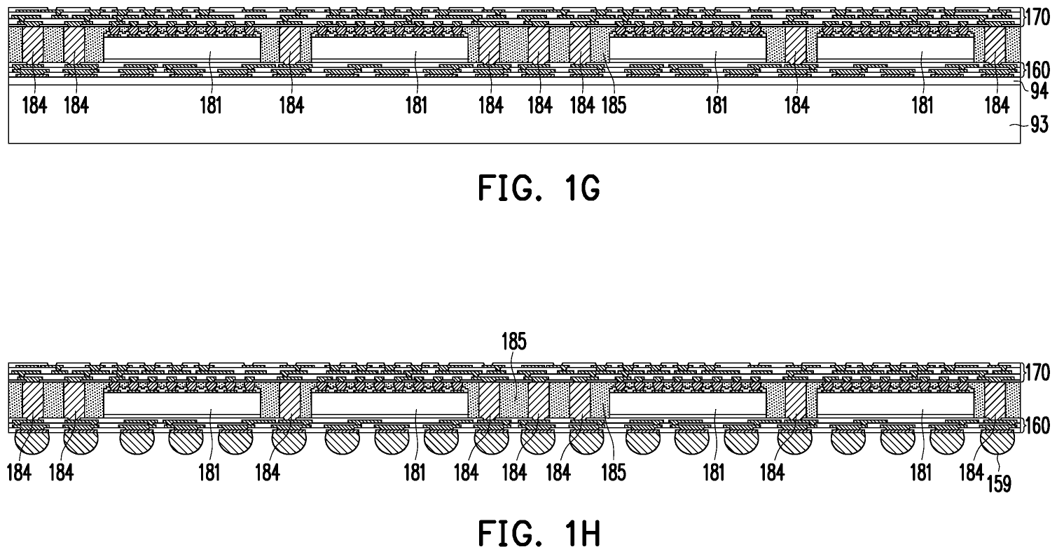

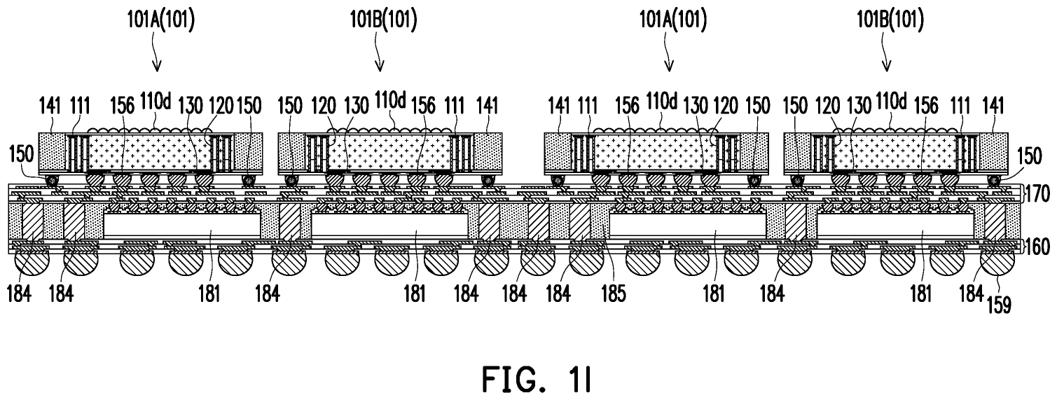

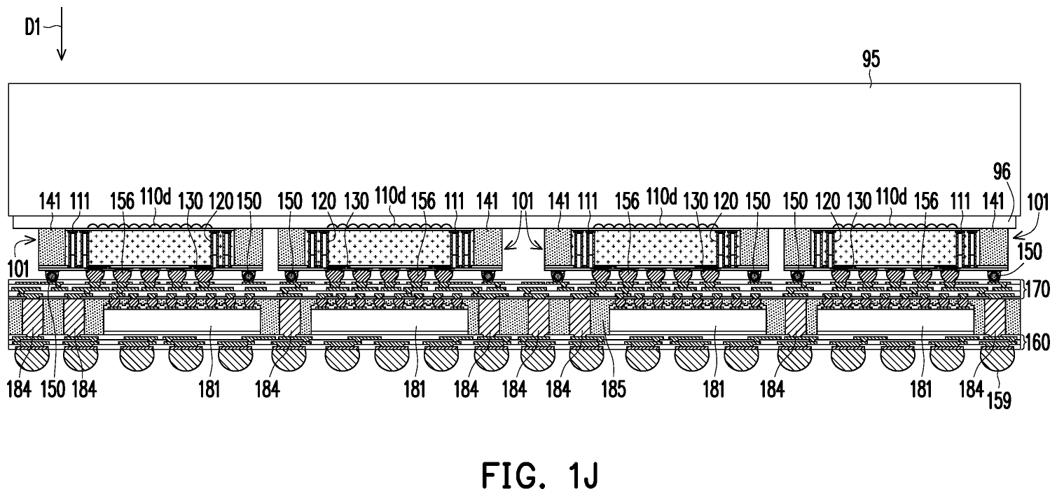

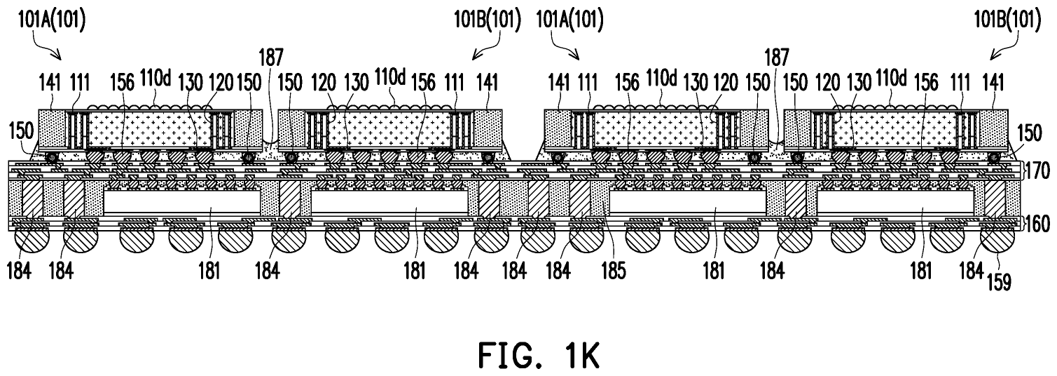

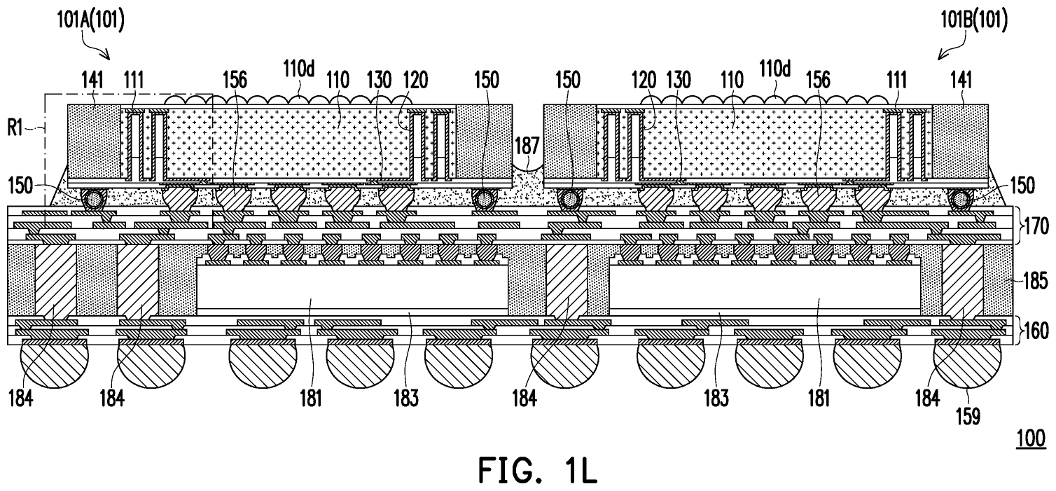

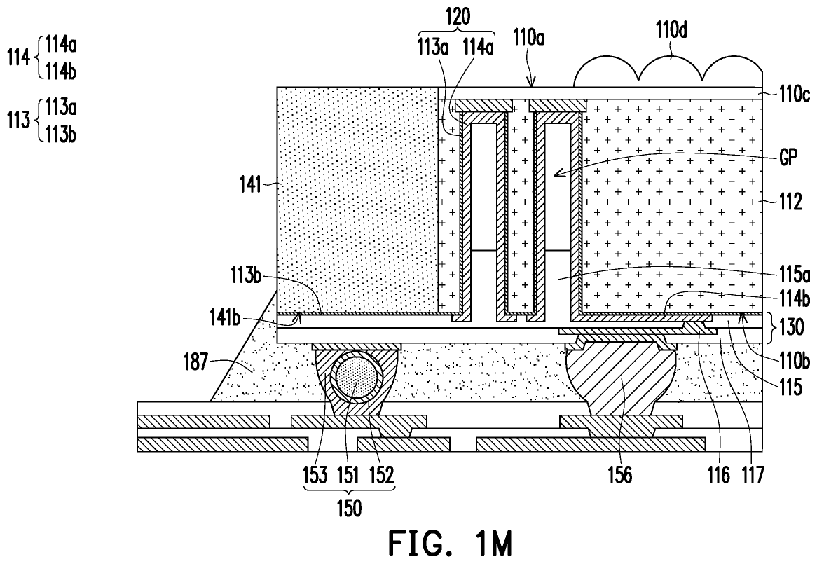

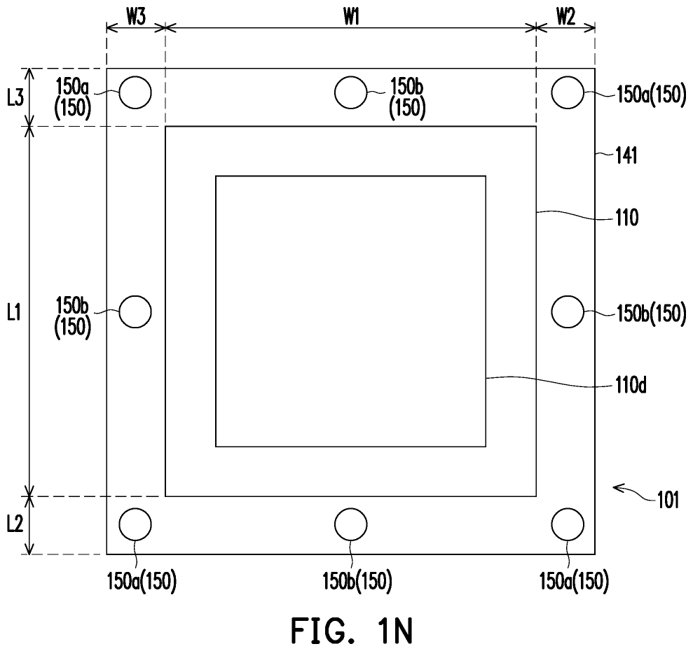

FIG. 1A to FIG. 1L are partial cross-sectional schematic views of a partial manufacturing method of a package structure according to the first embodiment of the disclosure.

Referring to FIG. 1A to FIG. 1D, a portion of the manufacturing method of a package 101 may be described as follows.

Referring to FIG. 1A, a carrier board 91 is provided. The disclosure has no special limitation on the carrier board 91, as long as the carrier board 91 is suitable for supporting the layers formed thereon or the devices disposed thereon.

In an embodiment, the carrier board 91 may have a release layer 92, but the disclosure is not limited thereto. The release layer 92 is, for example, a light to heat conversion (LTHC) adhesive layer or other similar release layers 92, and the disclosure is not limited thereto.

Please refer further to FIG. 1A. A plurality of chips 110 are disposed on the carrier board 91. In a direction parallel to the surface of the carrier plate 91, the distance between two adjacent chips 110 is at least 0.1 times the size of the chips 110.

In the present embodiment, there is a device region 110c at one side of the chips 110. For clarity of the overall drawing, the corresponding devices and/or circuits in the device region 110c are not shown in detail in FIG. 1A and other related drawings. The corresponding devices and/or circuits in the device region 110c may be formed by a common semiconductor manufacturing process. For example, the device region 110c may include a corresponding front end of line (FEOL) region and a back end of line (BEOL) region. The surface where the device region 110c is located may be referred to as an active surface 110a. A contact pad 111 may be disposed on the active surface 110a. In an embodiment, the contact pad 111 may be a die pad, and the devices in the device region may be electrically connected to the corresponding contact pad 111 via a corresponding back end of line (BEOL) interconnect. In an embodiment, the contact pad 111 may be a portion of the BEOL interconnect.

In the present embodiment, the active surface 110a has a photoelectric conversion region 110d. That is, the chips 110 may be photoelectric conversion chips. There may be a corresponding photoelectric conversion device in the photoelectric conversion region 110d. By adjusting the material in the photoelectric conversion region 110d (for example: by different doping elements, corresponding doping concentrations, and/or corresponding crystallinities), the photoelectric conversion region may be adapted to convert a corresponding optical signal into a corresponding electrical signal; or, the photoelectric conversion region may be adapted to convert a corresponding electrical signal into a corresponding optical signal.

In an embodiment, the sensing device is, for example, a complementary metal oxide semiconductor image sensor (CMOS image sensor; CIS), but the disclosure is not limited thereto. That is to say, the chips 110 may be sensing chips, and the photoelectric conversion region 110d is a corresponding sensing region.

In an embodiment, the sensing device is, for example, a light-emitting diode (LED), but the disclosure is not limited thereto. That is to say, the chips 110 may be LED chips, and the photoelectric conversion region 110d is a corresponding light-emitting region.

Referring to FIG. 1A to FIG. 1B, an encapsulant 141 covering the chips 110 is formed. Moreover, a through silicon via (TSV) 120 is formed in the chips 110, and a circuit structure 130 electrically connected to the TSV 120 is formed on a back surface (i.e., the surface opposite to the active surface 110a) 110b of the chips 110 opposite to the active surface 110a.

For example, a molding material (not shown) may be formed on the carrier board 91. Moreover, after the molding material is cured, a planarization process may be performed to form the encapsulant 141. The planarization process may be, for example, grinding, polishing, or other suitable planarization steps. The encapsulant 141 may expose the back surface 110b of the chips 110. That is to say, taking FIG. 1M as an example, a package surface 141b of the encapsulant 141 may be coplanar with the back surface 110b of the chips 110. In addition, during the planarization process, a portion of the chips 110 (e.g., a portion of the silicon substrate) may be slightly removed, but the disclosure is not limited thereto.

In the present embodiment, after the encapsulant 141 covering the chips 110 is formed, the TSV 120 and the corresponding circuit structure 130 may be formed from the back surface 110b of a silicon substrate 112. In addition, for clarity, a more detailed structure of the TSV 120 or the circuit structure 130 is exemplarily shown in FIG. 1M.

For example, an opening exposing the contact pad 111 may be formed from the back surface 110b of the silicon substrate 112 by etching or other suitable methods. Then, a corresponding insulating layer 113 may be formed by deposition, etching, and/or other suitable methods. The insulating layer 113 may expose the contact pad 111. A portion of an insulating layer 113a may cover the sidewall of the opening. A portion of an insulating layer 113b may cover the back surface 110b of the silicon substrate. Then, the corresponding conductive layer 114 may be formed by deposition, plating, etching, and/or other suitable methods. The conductive layer 114 includes, for example, a corresponding seed layer and a corresponding plating layer, but the disclosure is not limited thereto. The portion of a conductive layer 114a and the corresponding insulating layer 113a located in the opening may be referred to as the TSV 120. A portion of a conductive layer 114b disposed on the back surface 110b of the substrate may be a portion of the circuit structure 130. That is to say, a portion in the TSV 120 that is conductive and a portion in the circuit structure 130 that is conductive may be the same layer. Then, a corresponding insulating layer 115 may be formed on the conductive layer 114b by coating, semi-curing, etching, curing, and/or other suitable methods. A portion of an insulating layer 115a may be filled in the opening of the silicon substrate 112. Then, a corresponding conductive layer 116 or a corresponding insulating layer 117 may be formed on the insulating layer 115 by deposition, plating, etching, and/or other suitable methods. The number of the conductive layer 116 or the insulating layer 117 may be adjusted according to design requirements, which is not limited in the disclosure. In addition, the layout design of the circuit structure 130 may be adjusted according to design requirements, which is not limited in the disclosure.

In an embodiment, the material of the insulating layer 113 is, for example, silicon dioxide, silicon nitride, silicon oxynitride, other suitable inorganic insulating materials, or a stack or combination thereof.

In an embodiment, the material of the insulating layer 115 or the insulating layer 117 is, for example, polyimide (PI), other suitable organic insulating materials, or a stack or combination thereof.

In an embodiment, the insulating layer 115 and the conductive layer 114 do not completely fill the opening exposing the contact pad 111. That is to say, at least one gas gap GP is embedded in the TSV 120. For example, the step of forming the insulating layer 115 covering the TSV 120 (such as the step of forming an organic insulating material on the back surface 110b of the substrate) may be performed under an ambient pressure, and the ambient pressure is, for example, room pressure (e.g., about one atmospheric pressure). In this way, the insulating layer 115 may be formed more readily and/or quickly. That is to say, via the above method, the pressure of the gas gap GP is also substantially the above ambient pressure.

In an embodiment, the organic insulating material used to form the insulating layer 115 may be dissolved in a suitable solvent; or, it may be formed by performing a suitable reaction (such as condensation polymerization) in a suitable solvent. The solvent is, for example, dimethylformamide, dimethyl sulfoxide (DMSO), other suitable organic solvents, or co-solvent thereof. Therefore, during the process of forming the insulating layer 115 (for example, during the above curing step), a portion of the organic solvent molecules may remain in the gas gap GP.

Referring to FIG. 1B to FIG. 1C, limiting connectors 150 and connecting terminals 156 are formed on the circuit structure 130.

In an embodiment, the connecting terminals 156 and/or the limiting connectors 150 may be formed by, for example, a ball mounting process or suitable heating (e.g., a reflow process), but the disclosure is not limited thereto.

In an embodiment, the connecting terminals 156 may include a solder ball, but the disclosure is not limited thereto.

In an embodiment, the limiting connectors 150 are not structures made entirely of solder.

In an embodiment, as shown in FIG. 1M, the limiting connectors 150 may include a core 151 and a connecting layer. The connecting layer may cover the core 151. In an embodiment, the shape of the core 151 is the same or similar to a ball, but the disclosure is not limited thereto.

In an embodiment, the material of the core 151 may include polymer. In an embodiment, the core 151 may be a polymer core.

In another embodiment, the material of the core 151 may be a high-melting point metal (e.g., higher melting point than solder) and/or a hard metal (e.g., greater hardness than solder). For example, the core 151 may be a Cu core.

In an embodiment, the connecting layer may include an outer shell layer 153 and an inner shell layer 152. The inner shell layer 152 is disposed between the outer shell layer 153 and the core 151. The melting point of the outer shell layer 153 is lower than the melting point of the inner shell layer 152.

In an embodiment, the limiting connectors 150 disposed at suitable positions may improve the bonding quality of the package 101 in a subsequent process. For example, the polymer core 151 of the limiting connectors 150 may have suitable elasticity, and the polymer core 151 having a lower coefficient of thermal expansion (comparing with other polymer having a higher CTE) is covered by the inner shell layer 152 having a high melting point. In this way, during the bonding process of the package 101, under a suitable bonding pressure/temperature, the possibility of collapse of the whole structure or a portion of the structure (solder collapse during solder reflow) is reduced by the limiting connectors 150 capable of maintaining a suitable shape, so that a suitable distance or relative position between the package 101 and the object to be bonded (described later) may still be maintained, thus improving the bonding quality of the package 101.

In an embodiment, the Young's modulus of the polymer core 151 of the limiting connectors 150 may be between 4 GPa and 6 GPa. In an embodiment, the coefficient of thermal expansion of the polymer core 151 of the limiting connectors 150 may be between 35 ppm/° C. and 50 ppm/° C. within the temperature range of the above heating process (such as: reflow process).

In an embodiment, the polymer core 151 of the limiting connectors 150 may include a polymer containing divinylbenzene (DVB), other suitable polymers, a combination of the above, or a cross-link polymer including the above (such as: poly(styrene-co-divinylbenzene)). In an embodiment, the inner shell layer 152 may include a nickel layer, a copper layer, an alloy layer, or stacked layers of the above. In an embodiment, the outer shell layer 153 may include a tin (Sn) layer, a tin silver layer, an alloy layer, or stacked layers of the above.

It is worth noting that the disclosure does not limit the sequence of forming the limiting connectors 150 and forming the connecting terminals 156.

Referring to FIG. 1C to FIG. 1D, after the limiting connectors 150 and the connecting terminals 156 are disposed on the circuit structure 130, the carrier board 91 may be removed and/or a dicing step may be performed to form a plurality of packages 101. The dicing step is, for example, dicing with a rotating blade or a laser beam, but the disclosure is not limited thereto. It should be noted that the order of removing the carrier board 91 and performing the dicing step is not limited in the disclosure.

It is worth noting that after the dicing step is performed, similar reference numerals are used for the packages 101 after the dicing step. For example, the chips 110 (as shown in FIG. 1C) may be the chips 110 (as shown in FIG. 1D) after dicing, and the encapsulant 141 (as shown in FIG. 1C) may be the encapsulant 141 (as shown in FIG. 1D) after dicing, and so on. Elements in other preliminary structures will follow the same reference numeral rules described above, and will not be repeated or specifically shown herein.

It should be noted that, in an embodiment not shown, the limiting connectors 150 and/or the connecting terminals 156 may be formed on the circuit structure 130 after the above dicing step is performed.

Referring to FIG. 1E, a first redistribution circuit structure 160 is formed on the carrier board 93. The disclosure has no special limitation on the carrier board 93, as long as the carrier board 93 is suitable for supporting the layers formed thereon or the devices disposed thereon.

In an embodiment, the carrier board 93 may have a release layer 94, but the disclosure is not limited thereto. The release layer 94 is, for example, an LTHC adhesive layer or other similar release layers 94, and the disclosure is not limited thereto.

In the present embodiment, the first redistribution circuit structure 160 may include a corresponding conductive layer (not directly marked for the sake of simplicity and clarity in the drawing, such as the corresponding boxed region including oblique lines in the drawing) and a corresponding insulating layer (not directly marked for the sake of simplicity and clarity in the drawing, such as the corresponding blank boxed region included in the drawing). The first redistribution circuit structure 160 may be formed by a commonly used semiconductor process (e.g., coating process, deposition process, lithography process, and/or etching process), so details are not described herein. The number of the insulating layer and/or the conductive layer is not limited in the disclosure. For example, in the illustrated drawing (e.g., FIG. 1E), the first redistribution circuit structure 160 includes three insulating layers and three conductive layers. In addition, in FIG. 1E, the form of the insulating layers and/or the conductive layers is only shown as an example. For example, a corresponding portion in the conductive layers may form a corresponding circuit. In addition, the layout design of the above circuits may be adjusted according to design requirements, which is not limited in the disclosure.

Referring further to FIG. 1E, in the present embodiment, a plurality of conductive connectors 184 may be disposed or formed on the first redistribution circuit structure 160. The corresponding conductive connectors 184 may be electrically connected to the corresponding circuits in the first redistribution circuit structure 160.

In an embodiment, the conductive connectors 184 may include a pre-formed conductive member. For example, the conductive connectors 184 may include a pre-formed conductive pillar, but the disclosure is not limited thereto.

In an embodiment, the conductive connectors 184 may be formed by a commonly used semiconductor process (such as a lithography process, a sputtering process, an electroplating process, and/or an etching process), but the disclosure is not limited thereto. For example, the conductive connectors 184 may include a plating core layer and a seed layer surrounding the plating core layer, but the disclosure is not limited thereto.

Referring further to FIG. 1E, a plurality of chips 181 are disposed on the first redistribution circuit structure 160.

The chips 181 have an active surface 181a and a back surface 181b. The back surface 181b is opposite to the active surface 181a. In the present embodiment, the chips 181 may be disposed on the first redistribution circuit structure 160 in such a manner that the back surface 181b thereof faces the carrier board 93.

In the present embodiment, the active surface 181a of the chips 181 may have a plurality of metal bumps 182 thereon. In a subsequent step, the metal bumps 182 may reduce damage to the active surface 181a of the chips 181 and/or the devices in the chips 181.

In an embodiment, the back surface 181b of the chips 181 may have an adhesive layer 183 thereon. The adhesive layer 183 is, for example, a die attach film (DAF). The chips 181 may be fixed on the first redistribution circuit structure 160 by the adhesive layer 183.

In the present embodiment, the chips 181 do not have a TSV, but the disclosure is not limited thereto.

It should be noted that the order of forming the conductive connectors 184 and disposing the chips 181 is not limited in the disclosure.

Referring to FIG. 1E to FIG. 1F, an encapsulant 185 is formed on the first redistribution circuit structure 160. The encapsulant 185 may cover the chips 181 and the conductive connectors 184. The encapsulant 185 has a first encapsulating surface 185a and a second encapsulating surface 185b opposite to the first encapsulating surface 185a. The first encapsulating surface 185a is a surface facing the first redistribution circuit structure 160.

In an embodiment, a molding material (not shown) may be formed on the first redistribution circuit structure 160. Moreover, after the molding material is cured, a planarization process may be performed to form the encapsulant 185. The planarization process may be, for example, grinding, polishing, or other suitable planarization steps. The encapsulant 185 may expose the upper surface of the metal bumps 182 of the chips 181 and the upper surface of the conductive connectors 184. That is to say, the second encapsulating surface 185b of the encapsulant 185 may be coplanar with the upper surface of the metal bumps 182 of the chips 181 and the upper surface of the conductive connectors 184.

In an embodiment, since the active surface 181a of the chips 181 has the metal bumps 182 thereon, the possibility of damage to the active surface 181a of the chips 181 may be reduced during the above planarization step.

Referring to FIG. 1F to FIG. 1G, the second redistribution circuit structure 170 is formed on the second encapsulating surface 185b of the encapsulant 185. The second redistribution circuit structure 170 may include a corresponding conductive layer (not directly marked for the sake of simplicity and clarity in the drawing, such as the corresponding boxed region including oblique lines in the drawing) and a corresponding insulating layer (not directly marked for the sake of simplicity and clarity in the drawing, such as the corresponding blank boxed region in the drawing). The second redistribution circuit structure 170 may be formed by a commonly used semiconductor process (e.g., coating process, deposition process, lithography process, and/or etching process), so details are not described herein. The number of the insulating layer and/or the conductive layer is not limited in the disclosure. For example, in the illustrated drawing (e.g., FIG. 1G), the second redistribution circuit structure 170 includes four insulating layers and three conductive layers. In addition, in FIG. 1G, the form of the insulating layers and/or the conductive layers is only shown as an example. For example, a corresponding portion in the conductive layers may form a corresponding circuit. In addition, the layout design of the above circuits may be adjusted according to design requirements, which is not limited in the disclosure.

In an embodiment, the material of the insulating layers of the second redistribution circuit structure 170 may include an organic insulating material (such as polyimide (PI), but not limited thereto), but the disclosure is not limited thereto.

Referring to FIG. 1H, the carrier board 93 (marked in FIG. 1G) is removed, and then, connecting terminals 159 are formed on the first redistribution circuit structure 160. It should be noted that, in an embodiment not shown, the connecting terminals 159 may be formed after a certain step described later.

Referring to FIGS. 1I to 1J, a first package 101A (a type of the package 101) and a second package 101B (a type of the package 101) are disposed on the second redistribution circuit structure 170. A portion of the manufacturing method of the first package 101A and/or the second package 101B may be as shown in FIG. 1A to FIG. 1D.

For example, the package 101 (e.g., the first package 101A and/or the second package 101B) may be placed on the second redistribution circuit structure 170 as shown in FIG. 1I, so that the limiting connectors 150 and/or the connecting terminals 156 thereof are in contact with or abutted against a portion (may be referred to as a contact pad) of the topmost conductive layer in the second redistribution circuit structure 170.

Next, as shown in FIG. 1J, during the heating process of the limiting connectors 150 and the connecting terminals 156, a suitable pressure is applied to the plurality of packages 101 placed on the second redistribution circuit structure 170 by a leveling tool 95. In each of the packages 101, a plurality of limiting connectors 150 may be disposed close to the edge of the package 101 (e.g., disposed corresponding to four sides or four corners of the package 101), and the surface of the leveling tool 95 facing the plurality of packages 101 may be a flat surface. In this way, after a suitable pressure is applied to the plurality of packages 101 on the second redistribution circuit structure 170 by the leveling tool 95, the top surfaces of the plurality of packages 101 may be level, and the possibility of structural collapse may be reduced by the plurality of limiting connectors 150 of each of the packages 101.

In an embodiment, the leveling tool 95 may have a protective layer 96 thereon, but the disclosure is not limited thereto. The protective layer 96 may reduce damage to the packages 101 subjected to pressure, but the disclosure is not limited thereto.

In the present embodiment, in a direction D1 of applying pressure, in each of the packages 101, the plurality of limiting connectors 150 near the edge of the package 101 may be overlapped with the encapsulant 141 of the package 101. In this way, better cushioning may be provided when a suitable pressure is applied to the package 101.

In the present embodiment, in the direction of applying pressure, in each of the packages 101, the plurality of limiting connectors 150 near the edge of the package 101 may be not overlapped with a circuit in the circuit structure 130 of the package 101. In this way, when a suitable pressure is applied to the package 101, the possibility of damage to the circuit in the circuit structure 130 may be reduced.

In an embodiment, in the direction of applying pressure, in each of the packages 101, the plurality of limiting connectors 150 near the edge of the package 101 may possibly be overlapped with the conductive portion not used for signal transmission or not used for power transmission in the circuit structure 130 of the package 101.

In an embodiment, the limiting connectors 150 are not directly electrically connected to and/or not in contact with the chip 110 of each of the packages 101.

In an embodiment, the limiting connectors 150 are not directly electrically connected to the chip 110 in each of the packages 101 via the circuit structure 130 in each of the packages 101. For example, the limiting connectors 150 may possibly be connected to a conductive portion not used for signal transmission or not used for power transmission in the circuit structure 130 of the package 101. However, the above conductive portion is not directly connected to the chip 110 or the TSV 120 embedded in the chip 110.

In an embodiment, the limiting connectors 150 may be electrically connected to the chip 110 of each of the packages 101 via a corresponding circuit in the second redistribution circuit structure 170.

Referring to FIG. 1K, a filler 187 may be formed between the package 101 and the second redistribution circuit structure 170. The filler 187 is, for example, capillary underfill (CUF) or other suitable filling materials, but the disclosure is not limited thereto.

In an embodiment, the leveling tool 95 may still apply pressure on the plurality of packages 101 during a portion of the process of forming the filler 187. In an embodiment, the leveling tool 95 may be kept away from the packages 101 after the material used to form the filler 187 is cured to fix the packages 101 on the second redistribution circuit structure 170.

Referring to FIG. 1L, after the plurality of packages 101 are disposed on the second redistribution circuit structure 170, a dicing step may be performed to form a plurality of package structures 100. For example, the structure shown in FIG. 1K may be diced to form the plurality of package structures 100 as shown in FIG. 1L. The dicing step is, for example, dicing with a rotating blade or a laser beam, but the disclosure is not limited thereto.

It is worth noting that after the dicing step is performed, similar reference numerals are used for the package structures 100 after the dicing step. For example, the plurality of packages 101 (as shown in FIG. 1K) may be a plurality of packages 101 (as shown in FIG. 1L) after dicing, the first redistribution circuit structure 160 (as shown in FIG. 1K) may be a plurality of first redistribution circuit structures 160 (as shown in FIG. 1L) after dicing, the second redistribution circuit structure 170 (as shown in FIG. 1K) may be a plurality of second redistribution circuit structures 170 (as shown in FIG. 1L) after dicing, and so on. Elements in other preliminary structures will follow the same reference numeral rules described above, and will not be repeated or specifically shown herein.

In addition, for the sake of clarity, not all elements are marked in the drawings one by one. For example, not all of the limiting connectors 150, the connecting terminals 159, the TSVs 120, or the metal bumps 182, etc. are marked one by one. Moreover, in order to make the drawings concise and clear, the corresponding conductive layers and corresponding insulating layers in each of the circuit structures (such as the circuit structure 130, the second redistribution circuit structure 170, or the first redistribution circuit structure 160) are not directly marked.

It should be noted that, in the present embodiment, firstly, the carrier board 93 is removed, and then the connecting terminals 159 are formed on the first redistribution circuit structure 160, and then the dicing step is performed, but the disclosure is not limited thereto. In an embodiment not shown, the dicing step may be performed first, and then the carrier board 93 is removed, and then the connecting terminals 159 are formed on the first redistribution circuit structure 160. In an embodiment not shown, the carrier board 93 may be removed first, then the dicing step is performed, and then the connecting terminals 159 are formed on the first redistribution circuit structure 160.

After the above process, the manufacture of the package structures 100 of the present embodiment may be substantially completed.

FIG. 1L may be a schematic partial cross-sectional view of a package structure according to the first embodiment of the disclosure. FIG. 1M is a schematic partial cross-sectional view of a package structure according to the first embodiment of the disclosure. FIG. 1N is a schematic partial top view of a package structure according to the first embodiment of the disclosure. For example, FIG. 1M may be an enlarged view corresponding to a region R1 in FIG. 1L. FIG. 1N may be a schematic top view corresponding to one of the packages 101 in FIG. 1L. That is to say, if the package structures 100 are described, at least the contents and corresponding descriptions shown in FIG. 1L, FIG. 1M, and FIG. 1N need to be taken into consideration. Of course, a portion of the structural details may be related to the above manufacturing process. Therefore, if the package structures 100 are described, the contents and corresponding descriptions shown in FIG. 1A to FIG. 1L may also be considered. Moreover, in order to make the drawing concise and clear, only the projected outlines of the chips 110, the photoelectric conversion region 110d of the chips 110, the encapsulant 141, and a portion of the limiting connectors 150 are shown in FIG. 1N exemplarily.

Referring to FIG. 1L to FIG. 1N, the package structure 100 includes the first redistribution circuit structure 160, at least one chip 181 (may be referred to as: a third chip), the encapsulant 185 (may be referred to as: a third encapsulant), the second redistribution circuit structure 170, the conductive connector 184, a plurality of packages 101 (such as: the first package 101A and the second package 101B), and a plurality of limiting connectors 150. The chip 181 is disposed on the first redistribution circuit structure 160. The encapsulant 185 is disposed on the first redistribution circuit structure 160 and covers the chip 181. The second redistribution circuit structure 170 is disposed on the encapsulant 185 and electrically connected to the chip 181. The conductive connector 184 penetrates through the encapsulant 185. A corresponding circuit in the first redistribution circuit structure 160 and a corresponding circuit in the second redistribution circuit structure 170 may be electrically connected by the corresponding conductive connector 184. The plurality of packages 101 are disposed on the second redistribution circuit structure 170. The first package 101A includes a corresponding chip 110 (may be referred to as a first chip) and a corresponding encapsulant 141 (may be referred to as a first encapsulant) covering the chip 110. The second package 101B includes a corresponding chip 110 (may be referred to as a second chip) and a corresponding encapsulant 141 (may be referred to as a second encapsulant) covering the chip 110. The limiting connectors 150 are disposed between the corresponding packages 101 and the second redistribution circuit structure 170.

In an embodiment, the first package 101A may further include the circuit structure 130 (may be referred to as: a first circuit structure) disposed on the back surface 110b of the chip 110 (may be referred to as: a first chip) thereof; and/or the second package 101B may further include the circuit structure 130 (may be referred to as: a second circuit structure) disposed on the back surface 110b of the chip 110 (may be referred to as: a second chip) thereof.

In an embodiment, the chip 181 may be, for example, an electronic integrated circuit (EIC), an application-specific integrated circuit (ASIC), a control chip, or a chip including other suitable devices, but the disclosure is not limited thereto. In an embodiment, the number of the chip may be a plurality, and a plurality of third chips may be homogeneous chips or heterogeneous chips.

In an embodiment, the chips 110 may include sensing chips. The sensing range of the chip 110 included in the first package 101A is different from the sensing range of the chip 110 included in the second package 101B. In other words, the material of the photoelectric conversion region 110d of the chip 110 included in the first package 101A may be different from the material of the photoelectric conversion region 110d of the chip 110 included in the second package 101B. Moreover, the top surface of the first package 101A (e.g., in the thickness direction of the package structure 100, the surface of the first package 101A farthest from the first redistribution circuit structure 160) and the top surface of the second package 101 (e.g., the surface of the second package 101 farthest from the first redistribution circuit structure 160 in the thickness direction of the package structure 100) are level. The above thickness direction may be, for example, a direction perpendicular to the first encapsulating surface 185a (marked in FIG. 1F) or the second encapsulating surface 185b (marked in FIG. 1F).

In an embodiment, as shown in FIG. 1N, limiting connectors 150a (i.e., one of the limiting connectors 150) may be disposed corresponding to the four corners of the package 101. In an embodiment, as shown in FIG. 1N, limiting connectors 150b (i.e., one of the limiting connectors 150) may be disposed corresponding to the four sides of the package 101.

In an embodiment, the plurality of limiting connectors 150 near the edge of the package 101 may be overlapped with the encapsulant 141 of the package 101, and in a direction parallel to the surface (such as: the first encapsulating surface 185a or the second encapsulating surface 185b) of the encapsulant 141, the size (e.g., length or width) of the package 101 is 1.1 to 1.3 times the size (e.g., length or width) of the corresponding chip 110.

In an embodiment, a dimension W2 and a dimension W3 may be substantially the same. In this way, during the process of applying a suitable pressure and/or heating the connecting terminals 156 by the leveling tool 95 (shown in FIG. 1J), the exerting force or the receiving force may be more balanced. However, the disclosure is not limited thereto.

In an embodiment, a dimension L2 and a dimension L3 may be substantially the same. In this way, during the process of applying a suitable pressure and/or heating the connecting terminals 156 by the leveling tool 95 (shown in FIG. 1J), the exerting force or the receiving force may be more balanced. However, the disclosure is not limited thereto.

In an embodiment, the connecting terminals 156 are not structures made entirely of solder.

In an embodiment, the overall structure of the connecting terminals 156 is different from the overall structure of the limiting connectors 150. For example, the limiting connectors 150 include the high-polymer polymer core 151 that the connecting terminals 156 do not have.

In an embodiment, the overall material of the connecting terminals 156 is different from the overall material of the limiting connectors 150. For example, a portion of the material of the limiting connectors 150 is an insulator (such as the core 151), and the entire material of the connecting terminals 156 is a conductor.

In an embodiment, the overall conductivity of the connecting terminals 156 is different from the overall conductivity of the limiting connectors 150. For example, the overall conductivity of the connecting terminals 156 is greater than the overall conductivity of the limiting connectors 150.

In the present embodiment, during the manufacturing process of a package structure that is the same as or similar to the package structure 100, the process yield and/or the quality of the package structure may be improved by the limiting connectors 150 used. For example, in an embodiment where the chips 110 of the packages 101 are or include sensing chips, via the limiting connectors 150, a suitable pressure may be suitably applied by the leveling tool 95 (marked in FIG. 1J) in the above manufacturing process to level the top surfaces of the plurality of packages 101. In this way, for the above package structure suitable for sensing, the process yield and/or the sensing quality of the package structure may be improved. Moreover, the process yield and/or the sensing quality of the package structure may also be improved by the structure, material, or corresponding configuration of the above limiting connectors 150.

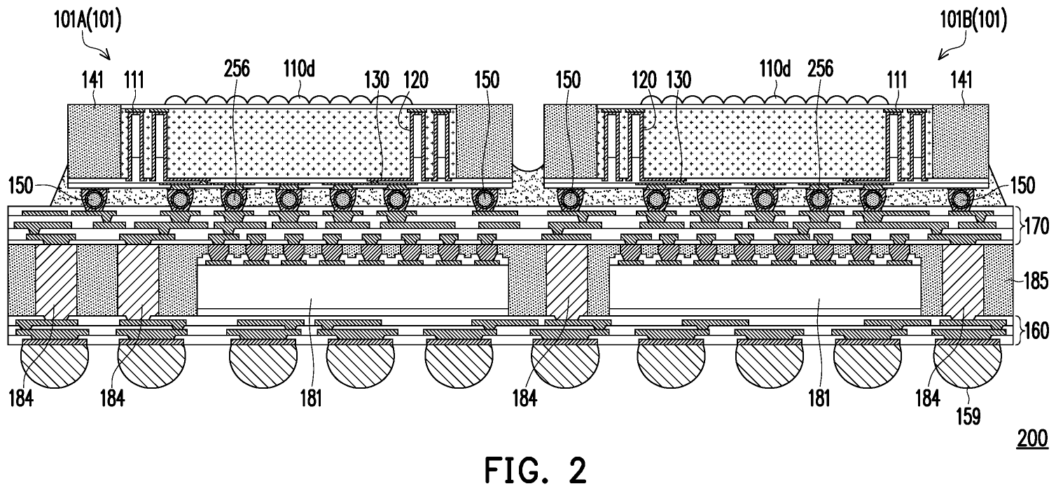

FIG. 2 is a schematic partial cross-sectional view of a package structure according to the second embodiment of the disclosure. A package structure 200 and a manufacturing method thereof of the present embodiment may be similar to the package structure 100 and the manufacturing method thereof, and similar members thereof are denoted by the same reference numerals, and have similar functions, materials, or forming methods, and descriptions thereof are omitted.

Referring to FIG. 2, the package structure 200 includes the first redistribution circuit structure 160, at least one chip 181, the encapsulant 185, the second redistribution circuit structure 170, the conductive connectors 184, the plurality of packages 101 (such as: the first package 101A and the second package 101B), the plurality of limiting connectors 150, and a plurality of connecting terminals 256. The packages 101 may be electrically connected to the corresponding circuits in the second redistribution circuit structure 170 via the corresponding connecting terminals 256.

In the present embodiment, the structure of the connecting terminals 256 may be the same as or similar to that of the limiting connectors 150. For example, the connecting terminals 256 may include a core (for example: a core that is the same as or similar to the core 151 of the limiting connectors 150) and (e.g.: a connecting layer that is the same as or similar to the connecting layer of the limiting connectors 150). For example, the connecting layer of the connecting terminals 256 may include (for example: an outer shell layer that is the same as or similar to the outer shell layer 153 of the limiting connectors 150) and (for example: an inner shell layer that is the same as or similar to the inner shell layer 152 of the limiting connectors 150).

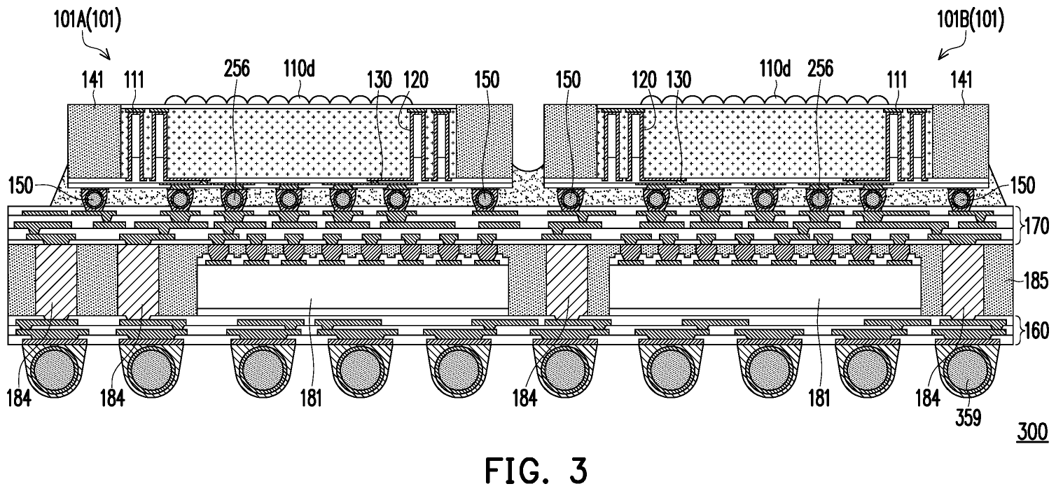

FIG. 3 is a schematic partial cross-sectional view of a package structure according to the third embodiment of the disclosure. A package structure 300 and a manufacturing method thereof of the present embodiment may be similar to the package structure 200 and the manufacturing method thereof, and similar members thereof are denoted by the same reference numerals, and have similar functions, materials, or forming methods, and descriptions thereof are omitted.

Referring to FIG. 3, the package structure 300 includes the first redistribution circuit structure 160, at least one chip 181, the encapsulant 185, the second redistribution circuit structure 170, the conductive connectors 184, the plurality of packages 101 (such as: the first package 101A and the second package 101B), the plurality of limiting connectors 150, and a plurality of connecting terminals 359. The corresponding connecting terminals 359 are electrically connected to the corresponding circuits in the first redistribution circuit structure 160.

In the present embodiment, the structure of the connecting terminals 359 may be the same as or similar to that of the limiting connectors 150. For example, the connecting terminals 359 may include a core (for example: a core that is the same as or similar to the core 151 of the limiting connectors 150) and (e.g.: a connecting layer that is the same as or similar to the connecting layer of the limiting connectors 150). For example, the connecting layer of the connecting terminals 359 may include (for example: an outer shell layer that is the same as or similar to the outer shell layer 153 of the limiting connectors 150) and (for example: an inner shell layer that is the same as or similar to the inner shell layer 152 of the limiting connectors 150).

Based on the above, in the manufacturing process of the package structure of the disclosure, the process yield and/or the quality of the package structure may be improved by the limiting connectors used.

What is claimed is:

1. A package structure, comprising:
a first redistribution circuit structure;
at least one third chip disposed on the first redistribution circuit structure;
a third encapsulant disposed on the first redistribution circuit structure and covering the third chip;
a second redistribution circuit structure disposed on the third encapsulant and electrically connected to the third chip;
a conductive connector penetrating through the third encapsulant so that the first redistribution circuit structure and the second redistribution circuit structure are electrically connected;
a first package disposed on the second redistribution circuit structure and comprising a first chip and a first encapsulant covering the first chip;
a second package disposed on the second redistribution circuit structure and comprising a second chip and a second encapsulant covering the second chip; and
a plurality of limiting connectors disposed between the first package and the second redistribution circuit structure and between the second package and the second redistribution circuit structure.

2. The package structure of claim 1, wherein each of the first chip and the second chip comprise a corresponding photoelectric conversion chip, and a top surface of the first package a top surface of the second package are coplanar.

3. The package structure of claim 1, wherein the limiting connectors are at least partially overlapped with the first encapsulant or the second encapsulant.

4. The package structure of claim 1, wherein the limiting connectors are not in contact with any of the first chip and the second chip.

5. The package structure of claim 1, wherein:
the first package further comprises a first circuit structure disposed on the first chip, the first circuit structure is electrically connected to the first chip, and the limiting connectors are not directly electrically connected to the first chip via the first circuit structure; or
the second package further comprises a second circuit structure disposed on the second chip, the second circuit structure is electrically connected to the second chip, and the limiting connectors are not directly electrically connected to the second chip via the second circuit structure.

6. The package structure of claim 1, wherein at least one of the first package and the second package corresponds to at least four of the limiting connectors, and the four limiting connectors respectively correspond to four sides or four corners of at least one in the first package and the second package.

7. The package structure of claim 1, wherein the limiting connectors comprise a core and a connecting layer covering the core.

8. The package structure of claim 7, wherein:
the connecting layer comprises an outer shell layer;
a material of the core is polymer; and
a material of the outer shell layer comprises a metal.

9. The package structure of claim 8, wherein:
the connecting layer further comprises an inner shell layer;
the inner shell is disposed between the outer shell layer and the core;
a material of the inner shell layer comprises a metal; and
a melting point of the outer shell layer is lower than a melting point of the inner shell layer.

10. The package structure of claim 7, wherein a material of the core is a high-melting point metal or a hard metal.

11. The package structure of claim 1, wherein the limiting connectors are not structures made entirely of solder.

12. The package structure of claim 1, further comprising:
a plurality of connecting terminals disposed between the first package and the second redistribution circuit structure and between the second package and the second redistribution circuit structure, wherein:
an overall structure of the connecting terminals is different from an overall structure of the limiting connectors;
an overall material of the connecting terminals is different from an overall material of the limiting connectors; or
an overall conductivity of the connecting terminals is different from an overall conductivity of the limiting connectors.

13. A package structure, comprising:
a first redistribution circuit structure;
a chip disposed on the first redistribution circuit structure;
a second redistribution circuit structure disposed on the chip;
a plurality of packages disposed on the second redistribution circuit structure, and each of the packages comprises an encapsulant; and
a plurality of limiting connectors disposed between each of the packages and the second redistribution circuit structure, and the limiting connectors are not structures made entirely of solder.

14. A manufacturing method of a package structure, comprising:
disposing at least one third chip on a first redistribution circuit structure;
forming a conductive connector on the first redistribution circuit structure;
forming a third encapsulant on the first redistribution circuit structure, wherein the third encapsulant covers the third chip;
after the conductive connector and the third encapsulant are formed, the conductive connector penetrates through the third encapsulant;
forming a second redistribution circuit structure on the third encapsulant, wherein the second redistribution circuit structure is electrically connected to the third chip, and the first redistribution circuit structure and the second redistribution circuit structure are electrically connected by the conductive connector; and
disposing a first package and a second package on the second redistribution circuit structure, and there are a plurality of limiting connectors between the first package and the second redistribution circuit structure and between the second package and the second redistribution circuit structure, wherein the first package comprises a first chip and a first encapsulant covering the first chip, and the second package comprises a second chip and a second encapsulant covering the second chip.
